(19) United States
(12) Patent Application Publication
(10) Pub. No.: US 2026/0068316 A1
(43) Pub. Date: Mar. 5, 2026

(54) INTEGRATED CIRCUIT AND LAYOUT METHODS FOR STANDARD CELL STRUCTURES

(71) Applicant: Taiwan Semiconductor Manufacturing Company, Ltd., Hsinchu (TW)

(72) Inventors: Yi-Yi Chen, New Taipei City (TW); Chi-Yu Lu, Hsinchu City (TW); Chih-Liang Chen, Hsinchu City (TW); Ya-Chi Chou, Hsinchu City (TW); Chen-Ling Wu, Hsinchu City (TW)

(73) Assignee: Taiwan Semiconductor Manufacturing Company, Ltd., Hsinchu (TW)

(21) Appl. No.: 19/035,343

(22) Filed: Jan. 23, 2025

Related U.S. Application Data
(60) Provisional application No. 63/690,477, filed on Sep. 4, 2024.

(51) Int. Cl. H10D 84/90

(52) U.S. Cl. CPC H10D 84/975

(57) ABSTRACT

An integrated circuit includes a plurality of cells abutted to one another, each of the plurality of cells corresponding to a respective circuit component. Each of the plurality of cells includes: a plurality of active regions extending along a first lateral direction; a plurality of gate structures extending along a second lateral direction perpendicular to the first lateral direction and traversing one or more of the plurality of active regions; a plurality of first interconnect structures extending along the first lateral direction and vertically disposed above the plurality of gate structure; and a plurality of second interconnect structures extending along the second lateral direction and vertically disposed above the plurality of first interconnect structures. Each of the plurality of second interconnect structures is shifted from a corresponding one of the plurality of gate structures with a distance along the first lateral direction.

### CROSS-REFERENCE TO RELATED APPLICATION

This application claims priority to and the benefit of U.S. Provisional Application No. 63/690,477, filed Sep. 4, 2024, entitled “METALLIZATION LAYER SHIFT FOR AUTO PLACE AND ROUTE,” which is incorporated herein by reference in its entirety for all purposes.

### BACKGROUND

The semiconductor integrated circuit (IC) industry has experienced exponential growth. In semiconductor IC design, standard cell methodologies are commonly used for the design of semiconductor devices on a chip. Standard cell methodologies use standard cells as abstract representations of certain functions to integrate millions devices on a single chip. As ICs continue to scale down, more and more devices are integrated into the single chip. This scaling down process generally provides benefits by increasing production efficiency and lowering associated costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a layout of an example standard cell including M1 tracks shifted toward a first direction, in accordance with some embodiments.

FIG. 2 illustrates a layout of an example standard cell including M1 tracks shifted to a second, opposite direction, in accordance with some embodiments.

FIG. 3 illustrates a layout including one or more of the standard cells shown in FIG. 1 and one or more of the standard cells shown in FIG. 2, in accordance with some embodiments.

FIG. 4 illustrates a cross-sectional view of an example semiconductor device, in accordance with some embodiments.

FIG. 5 illustrates a layout of an example standard cell including M1 tracks shifted toward a first direction, in accordance with some embodiments.

FIG. 6 illustrates a layout of an example standard cell including M1 tracks shifted to a second, opposite direction, in accordance with some embodiments.

FIG. 7 illustrates a layout of an example standard cell including M1 tracks shifted toward a first direction, in accordance with some embodiments.

FIG. 8 illustrates a layout of an example standard cell including M1 tracks shifted to a second, opposite direction, in accordance with some embodiments.

FIG. 9 illustrates a layout of an example standard cell including M1 tracks shifted toward a first direction, in accordance with some embodiments.

FIG. 10 illustrates a layout of an example standard cell including M1 tracks shifted to a second, opposite direction, in accordance with some embodiments.

FIG. 11 illustrates a layout of an example standard cell including M1 tracks shifted toward a first direction, in accordance with some embodiments.

FIG. 12 illustrates a layout of an example standard cell including M1 tracks shifted to a second, opposite direction, in accordance with some embodiments.

FIG. 13 illustrates an example flow chart of a method for optimizing cell placement, in accordance with some embodiments.

FIG. 14 illustrates an example computer system for implementing the disclosed method, in accordance with some embodiments.

FIG. 15 illustrates an example flow chart of a method for forming standard cell structures, in accordance with some embodiments.

FIG. 16 illustrates a flowchart of a method for forming a portion of an integrated circuit based on the layout of FIG. 1 and/or the layout of FIG. 2, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Generally, in standard cell methodologies, integrated circuits are designed by placing various standard cells with different functions. For example, these standard cells can be logic gates, such as an AND gate, an OR gate, an XOR gate, a NOT gate, a NAND gate, a NOR gate, and an XNOR gate, and combinational logic circuits such as a multiplexer, a flip-flop, an adder, and a counter. Standard cells can be implemented to realize complex integrated circuit functions. For convenience of integrated circuit design, a library including frequently used standard cells with their corresponding layouts are established. Accordingly, when designing an integrated circuit, a designer can select desired standard cells from the library and place the selected standard cells in an automatic placement and routing block, such that a layout of the integrated circuit can be created.

For example, when designing an integrated circuit having specific functions, standard cells are selected from a pre-designed standard cell library. Next, designers, or EDA (Electronic Design Automation) or ECAD (Electronic Computer-Aided Design) tools draw out design layouts of the integrated circuit including the selected standard cells and/or non-standard custom cells. The design layouts are converted to photomasks. Then, semiconductor integrated circuits can be manufactured, when patterns of various layers, defined by photography processes with the photomasks, are transferred to a substrate.

The existing standard cells typically includes one or more active regions extending in a first lateral direction and one or more gate structures extending in a second, perpendicular lateral direction, thereby operatively forming a respective number of transistors. Each of the existing standard cells further includes a plural number of middle-end and back-end interconnect structures connecting the transistors to one another or providing input/output pins, thereby operatively realizing a respective circuit function. The middle-end interconnect structures can be formed over the transistors (e.g., the active regions and the gate structures) to extend or allow their electrical connection, and the back-end interconnect structures can be formed across multiple metallization layers disposed over those middle-end interconnect structures.

For example, a first group of the back-end interconnect structures can be formed in a bottommost one of the metallization layers (sometimes referred to as M0 tracks), a second group of the back-end interconnect structures can be formed in a next bottommost one of the metallization layers (sometimes referred to as M1 tracks), and so on. Typically, the M0 tracks extend along the same direction as the active regions (e.g., the first lateral direction), and the M1 tracks extend along the same direction as the gate structures (e.g., the second lateral direction). Further, in the existing standard cell methodologies, the M1 tracks are often constrained to overlap with the gate structures or the middle-end interconnect structures. Such a constraint forces some of the M0 tracks to extend beyond the boundary of each standard cell, which disadvantageously limits flexibility on arrangement of the standard cells. For instance, with some of the M0 tracks sticking out of the boundary, abutting two or more of such standard cells to each other can cause some of the tracks to be shorted in an undesired manner. Thus, the existing standard cell methodologies are not entirely satisfactory in certain aspects.

The present disclosure provides various embodiments of systems and methods to design an integrated circuit using novel standard cells that each have its M1 tracks shifted away from corresponding gate structures with a distance. For example, the standard cell, as disclosed herein, can include a number of active regions extending in a first lateral direction and a number of gate structures extending in a second lateral direction perpendicular to the first lateral direction. The gate structures (parallel with one another) are spaced from one another with a first distance along the first lateral direction. Over the active regions and the gate structures, the standard cell can include a number of M0 tracks, extending in the first lateral direction, and a number of M1 tracks, extending in the second lateral direction. In various embodiments, instead of overlapping with a corresponding gate structure, each of those M1 tracks can be shifted away from the gate structure with a second distance along the first lateral direction. The second distance can be equal to or less than one half of the first distance. In this way, more access points on the M0 tracks can become available. Further, each of the M0 tracks can be immune from sticking out the cell boundary. Alternatively stated, the disclosed standard cell may have zero M0 track extending beyond the corresponding cell boundary. As a result, using the disclosed standard cells to form an integrated circuit can significantly improve flexibility on placing the similar standard cells, and advantageously increase a density of the standard cells in a given area.

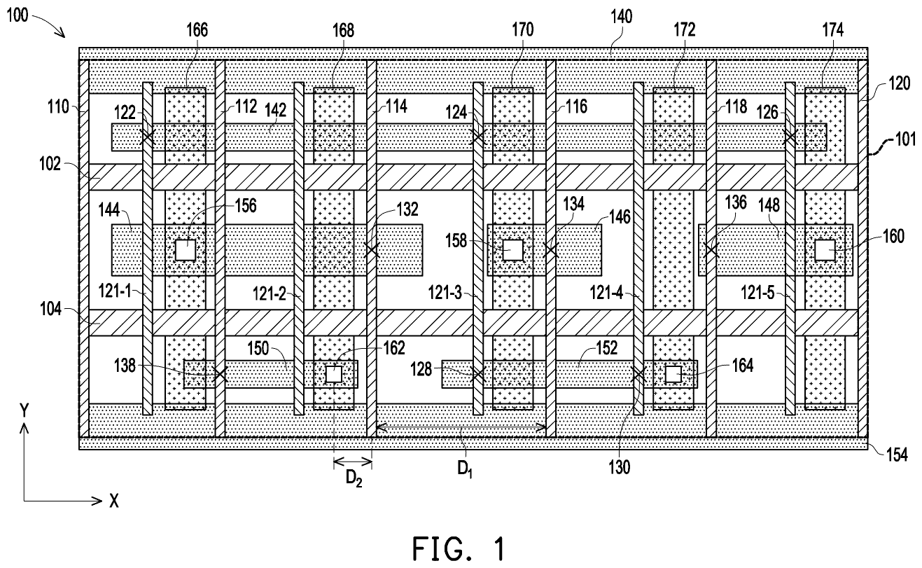

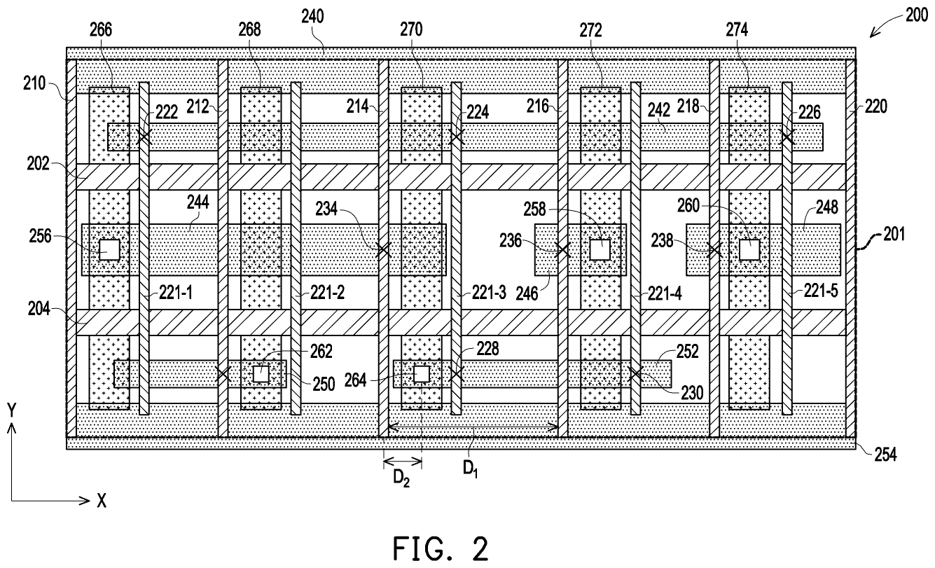

FIG. 1 and FIG. 2 illustrate layouts of example standard cells 100 and 200, respectively, in accordance with some embodiments. The standard cells 100 and 200 can operatively correspond to the same circuit component, e.g., an AND-OR-Inverter. It should be appreciated that the layouts of the standard cells 100 and 200 shown in FIGS. 1-2 have been simplified, and thus, each of the layouts can include any of various other components (e.g., patterns for forming respective structures) while remaining within the scope of the present disclosure.

In general, each of the layouts shown in FIGS. 1-2 (and the following figures) includes a plural number of patterns configured to form respective structures such as, for example, gate structures, middle-end interconnect structures, via structures, back-end interconnect structures, etc. Accordingly, such patterns of the disclosed layouts are herein referred to as the structures to be formed, respectively, in the following discussion.

Referring first to FIG. 1, the standard cell 100 includes a cell boundary 101. A cell boundary is a virtual line that can define the cell region of a corresponding standard cell, and the cell regions of neighboring standard cells do not overlap with each other. Surrounded by the cell boundary 101, the standard cell 100 may include one or more active regions 102 and 104 extending in the X-direction, gate structures 110, 112, 114, 116, 118, and 120 extending in the Y-direction, middle-end interconnect structures 121-1, 121-2, 121-3, 121-4, and 121-5 extending in the Y-direction, first via structures 122, 124, 126, 128, and 130, second via structures 132, 134, 136, and 138, first back-end interconnect structures 140, 142, 144, 146, 148, 150, 152, and 154 extending in the X-direction, third via structures 156, 158, 160, 162, and 164, and second back-end interconnect structures 166, 168, 170, 172, and 174 extending in the Y-direction.

In some embodiments, transistors of the standard cell 100 may each be formed as a gate-all-around (GAA) transistor. A GAA transistor can include a gate structure wrapping around each of multiple semiconductor nanostructures that collectively serve as its channel, with its source/drain structures physically disposed on opposite sides of the gate structure and electrically coupled to the channel. However, the transistors of the standard cell 100 can be formed as any of various other transistor structure while remaining within the scope of the present disclosure. For example, the transistors of the standard cell 100 can be formed as fin-based field-effect-transistors (FinFETs), planar transistors, complementary FETs (CFETs), nanowire transistors, etc.

In the example of GAA transistor structures, the active regions 102 and 104 can each be formed as a stack structure protruding from the frontside surface of a substrate. The stack includes a number of first semiconductor nanostructures (e.g., nanosheets) and second semiconductor nanostructures (e.g., nanosheets) extending along the X-direction, in which the first semiconductor nanostructures and the second semiconductor nanostructures are alternately stacked on top of one another. Following the formation of the stack, a number of dummy (e.g., polysilicon) gate structures, defined by the gate structures 110 to 120 shown in FIG. 1, can be formed to overlay the stack, defined by the active regions 102 and 104 shown in FIG. 1. Next, respective portions of the first and second semiconductor nanostructures in the stack that are overlaid by the dummy gate structures remain, while other portions are replaced with a number of epitaxial structures. Next, the dummy gate structures, together with the remaining portions of the second semiconductor nanostructures, are replaced by a number of active (e.g., metal) gate structures. The remaining portions of the first semiconductor nanostructures can be configured as the channel of a corresponding transistor, and the epitaxial structures coupled to both ends of the channel (e.g., along the X-direction) can be configured as source/drain structures (or terminals) of the transistor, and the active gate structures that each overlay (e.g., wrap around) the remaining portions of the first semiconductor nanostructures can be configured as a gate terminal of the transistor.

Following the formation of the transistors (based on the active regions 102 to 104 and the gate structures 110 to 120), the middle-end interconnect structures 121-1 to 121-5 can be formed to each electrically contact the epitaxial structure (source/drain terminal) of a corresponding transistor. These middle-end interconnect structures 121-1 to 121-5 generally extend in the Y-direction, and are each interposed between adjacent ones of the gate structures 110 to 120. As a representative example, the middle-end interconnect structure 121-1 is interposed between the gate structures 110 and 112. Further, each of the middle-end interconnect structures 121-1 to 121-5 is spaced from each of the corresponding gate structures (e.g., the nearest gate structure) with one half of a distance “D₁” separating the gate structures along the X-direction. This separation distance D₁ is sometimes referred to as a pitch of the gate structures 110 to 120. Such middle-end interconnect structures 121-1 to 121-5 are sometimes referred to as MDs.

Following the formation of the MDs 121-1 to 121-5, the first via structures 122 to 130 and the second via structures 132 to 138 can be formed. The first via structures 122 to 130 are each coupled to a corresponding one of the MDs 121-1 to 121-5, and the second via structures 132 to 138 are each coupled to a corresponding one of the gate structures 110 to 120. The first via structures 122 to 130 are sometimes referred to as VDs, and the second via structures 132 to 138 are sometimes referred to as VGs. These VDs and VGs allow the underlying source/drain terminals (through the MDs) and gate terminals to electrically connect to respective back-end interconnect structures (e.g., the first back-end interconnect structures 140 to 154, the second back-end interconnect structures 166 to 174), which will be discussed as follows.

In some embodiments, the first back-end interconnect structures 140 to 154 can extend in the same direction as the active regions 102 and 104 (e.g., the X-direction) and be formed in a bottommost one of plural metallization layers disposed over the frontside surface of the substrate. Each of these metallization layers can include (e.g., embed) a plural number of metal tracks in one or more dielectric layers (e.g., formed of an oxide material or a low-k dielectric material). Such a bottommost metallization layer is sometimes referred to as M0 layer, and accordingly, the first back-end interconnect structures 140 to 154 can sometimes be referred to as M0 tracks. The second back-end interconnect structures 166 to 174 can extend in the same direction as the gate structures (e.g., the Y-direction) and be formed in a next bottommost one of plural metallization layers. This next bottommost metallization layer is sometimes referred to as M1 layer, and accordingly, the second back-end interconnect structures 166 to 174 can sometimes be referred to as M1 tracks. The M0 tracks (e.g., 140 to 154) can each be coupled to a corresponding one of the M1 tracks (e.g., 166 to 174) through one or more of the third via structures 156 to 164, which are sometimes referred to as V0s.

As shown in FIG. 1, the M0 tracks 140 and 154, that are formed along edges of the cell boundary 101, can be configured as power rails to carry a first supply voltage (e.g., VDD) and a second supply voltage (e.g., VSS), respectively. The M0 track 142 can be coupled to the underlying MDs 121-1, 121-3, and 121-5e through the VDs 122, 124, and 126, respectively. The M0 track 144 can be coupled to the gate structure 114 through the VG 132. The M0 track 146 can be coupled to the gate structure 116 through the VG 134. The M0 track 148 can be coupled to the gate structure 118 through the VG 136. The M0 track 150 can be coupled to the gate structure 112 through the VG 138. The M0 track 152 can be coupled to the underlying MDs 121-3 and 121-4 through the VDs 128 and 130, respectively. The M1 track 166 can be coupled to the M0 track 144 through the V0 156. The M1 track 168 can be coupled to the M0 track 150 through the V0 162. The M1 track 170 can be coupled to the M0 track 146 through the V0 158. The M1 track 172 can be coupled to the M0 track 152 through the V0 164. The M1 track 174 can be coupled to the M0 track 148 through the V0 160.

In some embodiments of the present disclosure, the M1 tracks 166 to 174 are shifted away from the respective gate structures 112 to 120 in the X-direction. Specifically, each of the M1 tracks 166 to 174 is shifted to the left from a corresponding (e.g., nearest) one of the gate structures 112 to 120 with a distance, “D₂.” The distance D₂ may be equal to or less than one half of the separation distance D₁ (e.g., the pitch of the gate structures 110 to 120). Neighboring ones of the MDs 121-1 to 121-5 may be separated with the same pitch D₁. Accordingly, each of the M1 tracks 166 to 174 may be referred to as shifting toward a corresponding one of the MDs 121-1 to 121-5 with a distance (e.g., D₁-D₂). By laterally shifting the M1 tracks with respect to the corresponding gate structures or MDs, more access points on some of the M0 tracks can be provided, which advantageously causes each of the M0 tracks to not extend beyond the cell boundary 101 (as shown in FIG. 1).

Referring next to FIG. 2, the standard cell 200 is substantially similar to the standard cell 100 except that the standard cell 200 may have its M1 tracks shifted from the respective gate structures to the right. For example, the standard cell 200 includes a cell boundary 201, and surrounded by the cell boundary 201, the standard cell 200 may include one or more active regions 202 and 204 extending in the X-direction, gate structures 210, 212, 214, 216, 218, and 220 extending in the Y-direction, middle-end interconnect structures (MDs) 221-1, 221-2, 221-3, 221-4, and 221-5 extending in the Y-direction, first via structures (VDs) 222, 224, 226, 228, and 230, second via structures (VGs) 232, 234, 236, and 238, first back-end interconnect structures (M0 tracks) 240, 242, 244, 246, 248, 250, 252, and 254 extending in the X-direction, third via structures (V0s) 256, 258, 260, 262, and 264, and second back-end interconnect structures (M1 tracks) 266, 268, 270, 272, and 274 extending in the Y-direction.

As shown, each of the M1 tracks 266 to 274 is shifted to the right from a corresponding (e.g., nearest) one of the gate structures 212 to 220 with the distance D₂. The distance D₂ may be equal to or less than one half of the separation distance D₁ (e.g., the pitch of the gate structures 210 to 220). Neighboring ones of the MDs 221-1 to 221-5 may be separated with the same pitch D₁. Accordingly, each of the M1 tracks 266 to 274 may be referred to as shifting toward a corresponding one of the MDs 221-1 to 221-5 with a distance (e.g., D₁-D₂). By laterally shifting the M1 tracks with respect to the corresponding gate structures or MDs, more access points on some of the M0 tracks can be provided, which advantageously causes each of the M0 tracks to not extend beyond the cell boundary 201 (as shown in FIG. 2).

With these two types of standard cells 100 and 200 (corresponding to the same circuit component), an integrated circuit can be formed to include an increased number of the circuit component. For example, the standard cell 200 can be flipped with respect to the Y-direction and freely inserted into any adjacent standard cells 100 disposed along the X-direction, or the standard cell 100 can be flipped with respect to the Y-direction and freely inserted into any adjacent standard cells 200 disposed along the X-direction. Stated another way, each of the standard cell 200 or 100, upon being flipped, can be interposed between a pair of the standard cells 100 or 200. By flipping some of the standard cells and inserting into neighboring ones of the other standard cells, a density of the standard cells can be significantly increase. Given that none of the M0 tracks (of the standard cell 100 or 200) sticking out of its cell boundary, inserting the flipped standard cell into the neighboring non-flipped standard cells can be immune from shorting the respective metal tracks.

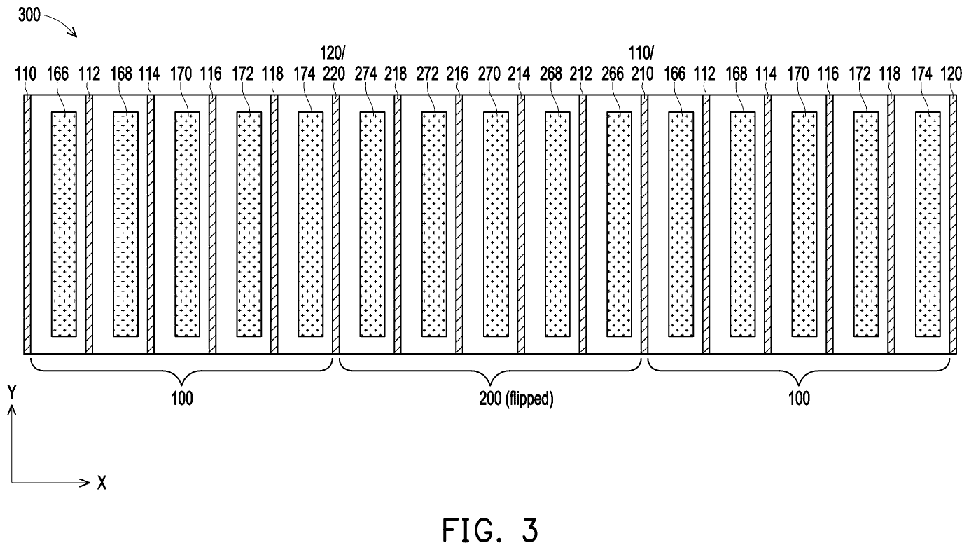

FIG. 3 illustrates a portion of a layout 300 for forming an integrated circuit, in accordance with some embodiments. The layout 300 can include two of the standard cells 100 sandwiching one of the standard cells 200 being flipped. It should be appreciated that, solely for purposes of clarity, some of the components of the standard cells 100 and 200 (e.g., the active regions 102-104, the MDs 121-1 to 121-5, the M0 tracks 140 to 154, the active regions 202-204, the MDs 221-1 to 221-5, the M0 tracks 240 to 254) are not shown in FIG. 3. As shown, after flipping the standard cell 200, the M1 tracks 266 to 274 are each shifted to the left from the corresponding gate structure. As such, all the M1 tracks, across the layout 300, are shifted to the same direction, which can advantageously maximize the density of the standard cells that can be placed in a given area.

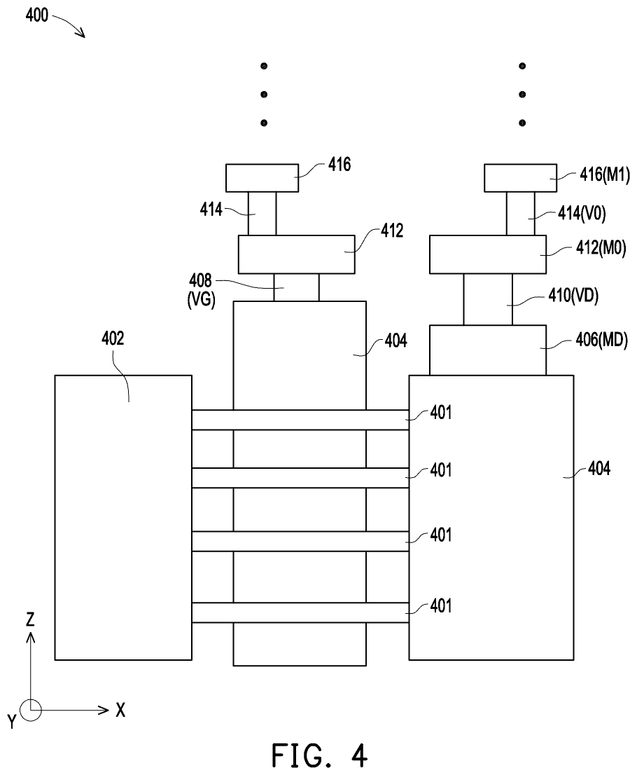

FIG. 4 illustrates a cross-sectional view of a portion of a semiconductor device 400 including the components formed based on the layout shown in FIG. 1 or 2, in accordance with some embodiments. For example, the cross-sectional view of FIG. 4 is cut along the lengthwise direction of an active region (e.g., the X-direction). It should be appreciated that the cross-sectional view of FIG. 4 is provided merely for illustrative purposes, and does not intend to limit the scope of the present disclosure.

As shown, the semiconductor device 400 includes a number of nanostructures 401 extending in the X-direction and disposed over a substrate. The nanostructures 401 are vertically spaced from one another. Each of the nanostructures 401 has a first end and a second end connected to a first epitaxial structure 402 and a second epitaxial structure 402. Each of the nanostructures 401 is wrapped by a gate structure 404. The nanostructures 401 can operatively serve as the channel of a transistor. Further, the epitaxial structures 402 can operatively serve as source and drain terminals of the transistor, and the gate structure 404 can operatively serve as a gate terminal of the transistor. The nanostructures, the epitaxial structures, and the gate structures are typically referred to as part of front-end processing. In some embodiments, the nanostructures 401 can be formed based on the active region of the layout shown in FIG. 1/2, and the gate structure 404 can be formed based on the gate structures of the layout shown in FIG. 1/2.

The semiconductor device 400 further includes an MD 406 connected to the epitaxial structure 402, a VG 408 connected to the gate structure 404, a VD 410 connected to the MD 406. The MD 406 can extend along the same direction as the gate structure 404 (e.g., the Y-direction). In some embodiments, the MDs, the VDs, and the VGs are typically referred to as part of middle-end processing. The semiconductor device 400 further includes a number of M0 tracks 412, some of which are connected to the VD and some of which are connected to the VG, and a number of M1 tracks 416, each of which is coupled to a corresponding one of the M0 tracks 412 through a V0 414. The M0 tracks 412 can extend along the same direction as the nanostructures 401 (e.g., the X-direction), and the M1 tracks 416 can extend along the same direction as the gate structure 404 (e.g., the Y-direction). In some embodiments, the M0 tracks, the V0s, and the M1 tracks are typically referred to as part of back-end processing.

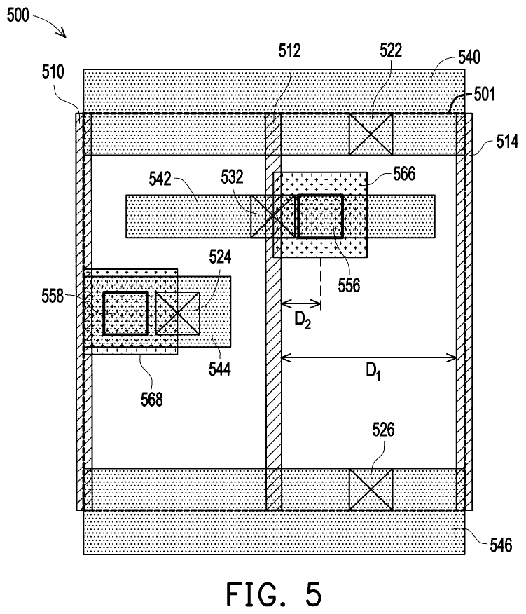

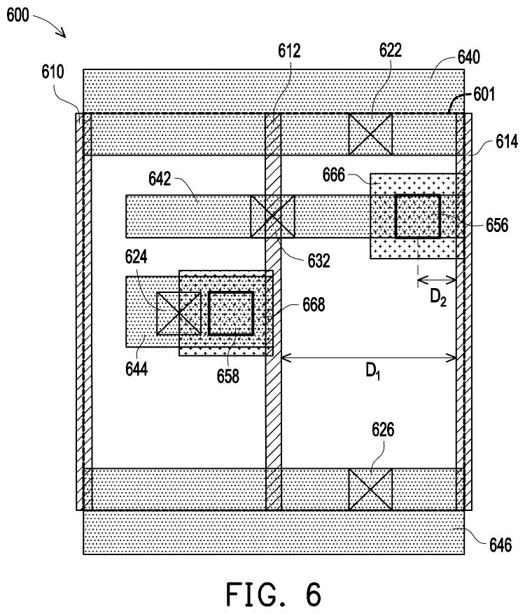

FIG. 5 and FIG. 6 illustrate layouts of example standard cells 500 and 500, respectively, in accordance with some embodiments. The standard cells 500 and 600 can operatively correspond to the same circuit component, e.g., an inverter. It should be appreciated that the layouts of the standard cells 500 and 600 shown in FIGS. 5-6 have been simplified, and thus, each of the layouts can include any of various other components (e.g., patterns for forming respective active regions, MDs, etc.) while remaining within the scope of the present disclosure.

Referring first to FIG. 5, the standard cell 500 includes a cell boundary 501. Surrounded by the cell boundary 501, the standard cell 500 may include one or more active regions extending in the X-direction (not shown for clarity), gate structures 510, 212, and 514 extending in the Y-direction, MDs extending in the Y-direction (not shown for clarity), VDs 522, 524, and 526, VG 532, M0 tracks 540, 542, 544, and 546 extending in the X-direction, V0s 556 and 558, and M1 tracks 566 and 568. As shown, the M1 track 566 is shifted to the right from the gate structure 512 with the distance D₂ which can be equal to or less than the gate pitch D₁, and the M1 track 568 is shifted to the right from the gate structure 510 with the distance D₂.

Referring next to FIG. 6, the standard cell 600 includes a cell boundary 601. Surrounded by the cell boundary 601, the standard cell 600 may include one or more active regions extending in the X-direction (not shown for clarity), gate structures 610, 612, and 614 extending in the Y-direction, MDs extending in the Y-direction (not shown for clarity), VDs 622, 624, and 626, VG 632, M0 tracks 640, 642, 644, and 646 extending in the X-direction, V0s 656 and 658, and M1 tracks 666 and 668. As shown, the M1 track 666 is shifted to the left from the gate structure 614 with the distance D₂ which can be equal to or less than the gate pitch D₁, and the M1 track 668 is shifted to the left from the gate structure 612 with the distance D₂.

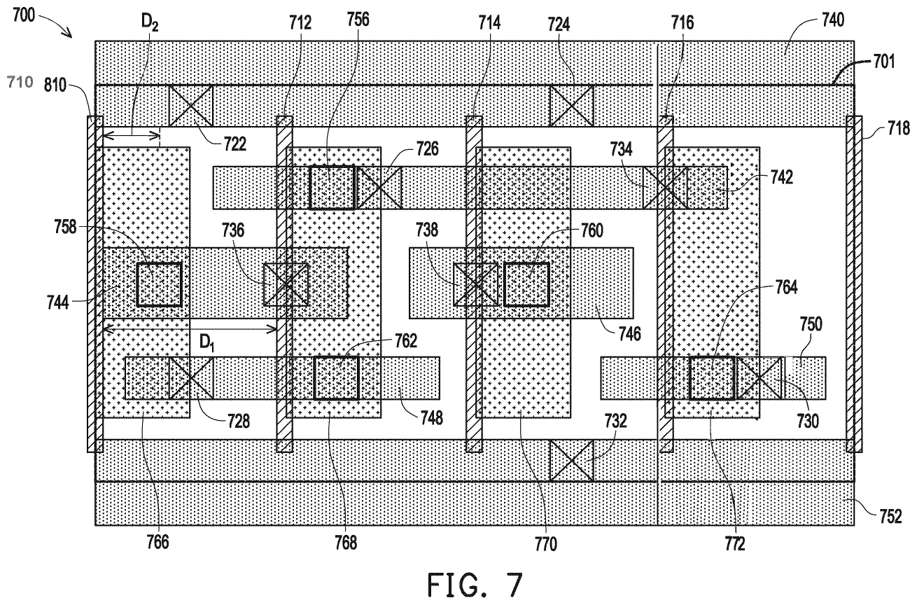

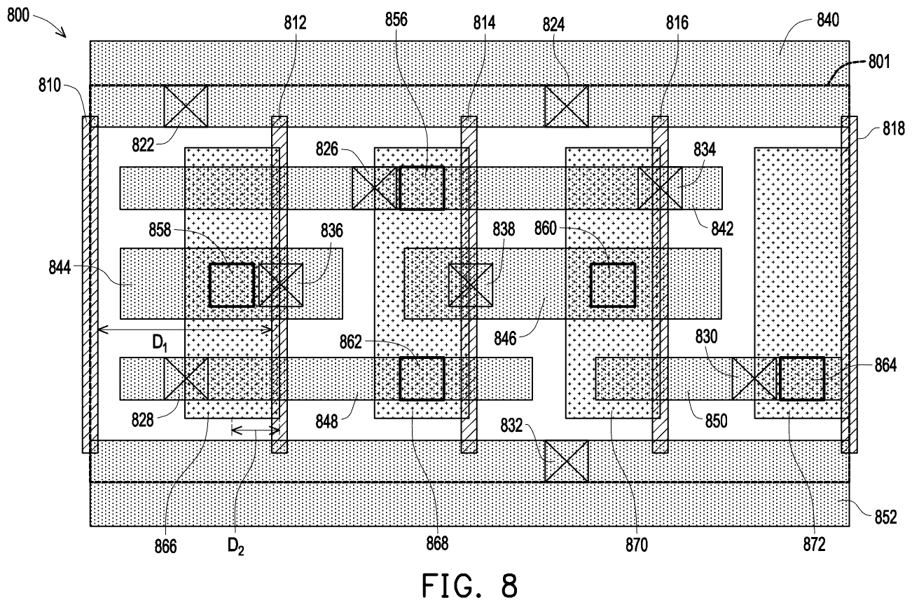

FIG. 7 and FIG. 8 illustrate layouts of example standard cells 700 and 800, respectively, in accordance with some embodiments. The standard cells 700 and 800 can operatively correspond to the same circuit component, e.g., an AND gate. It should be appreciated that the layouts of the standard cells 700 and 800 shown in FIGS. 7-8 have been simplified, and thus, each of the layouts can include any of various other components (e.g., patterns for forming respective active regions, MDs, etc.) while remaining within the scope of the

### Present Disclosure.

Referring first to FIG. 7, the standard cell 700 includes a cell boundary 701. Surrounded by the cell boundary 701, the standard cell 700 may include one or more active regions extending in the X-direction (not shown for clarity), gate structures 710, 712, 714, 716, and 718 extending in the Y-direction, MDs extending in the Y-direction (not shown for clarity), VDs 722, 724, 726, 728, 730, and 732, VGs 734, 736, and 738, M0 tracks 740, 742, 744, 746, 748, 750, and 752 extending in the X-direction, V0s 756, 758, 760, 762, and 764, and M1 tracks 766, 768, 770, and 772. As shown, the M1 track 766 is shifted to the right from the gate structure 710 with the distance D₂ which can be equal to or less than the gate pitch D₁, the M1 track 768 is shifted to the right from the gate structure 712 with the distance D₂, the M1 track 770 is shifted to the right from the gate structure 714 with the distance D₂, and the M1 track 772 is shifted to the right from the gate structure 716 with the distance D₂.

Referring first to FIG. 8, the standard cell 800 includes a cell boundary 801. Surrounded by the cell boundary 801, the standard cell 800 may include one or more active regions extending in the X-direction (not shown for clarity), gate structures 810, 812, 814, 816, and 818 extending in the Y-direction, MDs extending in the Y-direction (not shown for clarity), VDs 822, 824, 826, 828, 830, and 832, VGs 834, 836, and 838, M0 tracks 840, 842, 844, 846, 848, 850, and 852 extending in the X-direction, V0s 856, 858, 860, 862, and 864, and M1 tracks 866, 868, 870, and 872. As shown, the M1 track 866 is shifted to the left from the gate structure 812 with the distance D₂ which can be equal to or less than the gate pitch D₁, the M1 track 868 is shifted to the left from the gate structure 814 with the distance D₂, the M1 track 870 is shifted to the left from the gate structure 816 with the distance D₂, and the M1 track 872 is shifted to the left from the gate structure 818 with the distance D₂.

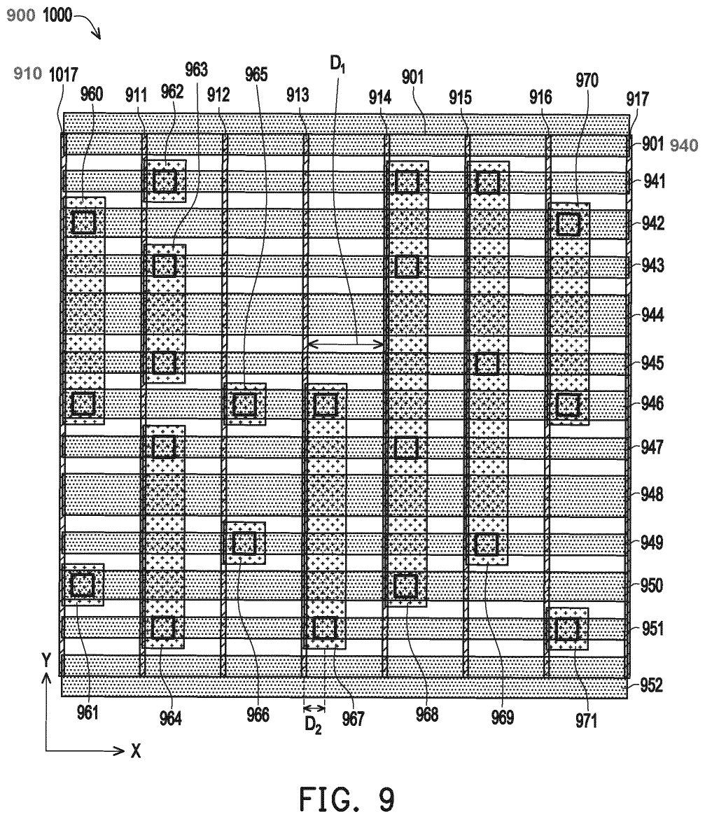

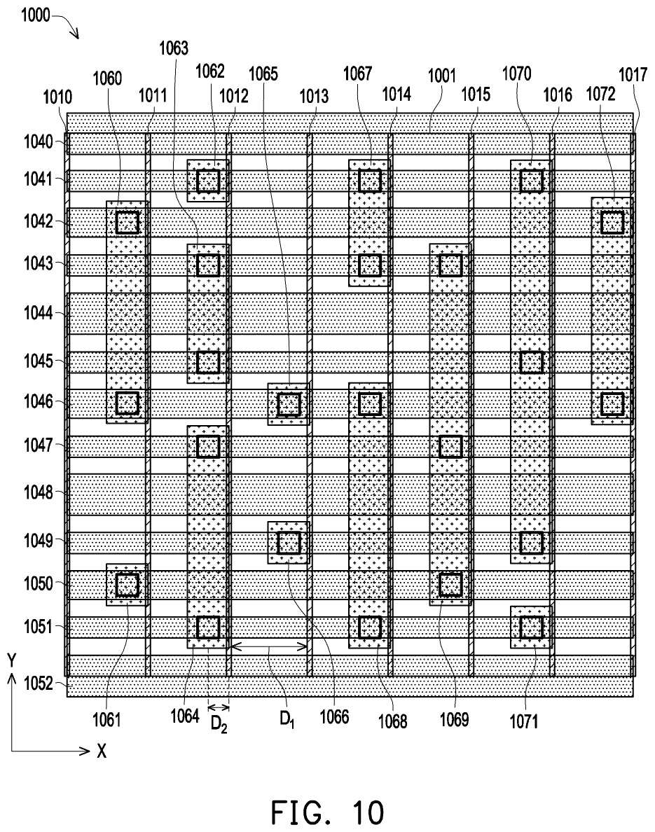

FIG. 9 and FIG. 10 illustrate layouts of example standard cells 900 and 1000, respectively, in accordance with some embodiments. The standard cells 900 and 1000 can operatively correspond to the same circuit component, e.g., a flip flop. It should be appreciated that the layouts of the standard cells 900 and 1000 shown in FIGS. 9-10 have been simplified, and thus, each of the layouts can include any of various other components (e.g., patterns for forming respective active regions, MDs, VDs, VGs, etc.) while remaining within the scope of the present disclosure.

Referring first to FIG. 9, the standard cell 900 includes a cell boundary 901. Within the cell boundary 901, the standard cell 900 may include one or more active regions extending in the X-direction (not shown for clarity), gate structures 910, 911, 912, 913, 914, 915, 916, and 917 extending in the Y-direction, MDs extending in the Y-direction (not shown for clarity), M0 tracks 940, 941, 942, 943, 944, 945, 946, 947, 948, 949, 950, 951, and 952 extending in the X-direction, and M1 tracks 960, 961, 962, 963, 964, 965, 966, 967, 968, 969, 970, and 971. As shown, the M1 tracks 960 and 961 are each shifted to the right from the gate structure 910 with the distance D₂ which can be equal to or less than the gate pitch D₁, the M1 tracks 962, 963, and 964 are each shifted to the right from the gate structure 911 with the distance D₂, the M1 tracks 965 and 966 are each shifted to the right from the gate structure 912 with the distance D₂, the M1 track 967 is shifted to the right from the gate structure 913 with the distance D₂, the M1 track 968 is shifted to the right from the gate structure 914 with the distance D₂, the M1 track 969 is shifted to the right from the gate structure 915 with the distance D₂, and the M1 tracks 970 and 971 are each shifted to the right from the gate structure 916 with the distance D₂.

Referring next to FIG. 10, the standard cell 1000 includes a cell boundary 1001. Within the cell boundary 1001, the standard cell 1000 may include one or more active regions extending in the X-direction (not shown for clarity), gate structures 1010, 1011, 1012, 1013, 1014, 1015, 1016, and 1017 extending in the Y-direction, MDs extending in the Y-direction (not shown for clarity), M0 tracks 1040, 1041, 1042, 1043, 1044, 1045, 1046, 1047, 1048, 1049, 1050, 1051, and 1052 extending in the X-direction, and M1 tracks 1060, 1061, 1062, 1063, 1064, 1065, 1066, 1067, 1068, 1069, 1070, 1071, and 1072. As shown, the M1 tracks 1060 and 1061 are each shifted to the left from the gate structure 1011 with the distance D₂ which can be equal to or less than the gate pitch D₁, the M1 tracks 1062, 1063, and 1064 are each shifted to the left from the gate structure 1012 with the distance D₂, the M1 tracks 1065 and 1066 are each shifted to the left from the gate structure 1013 with the distance D₂, the M1 tracks 1067 and 1068 are each shifted to the left from the gate structure 1014 with the distance D₂, the M1 track 1069 is shifted to the left from the gate structure 1015 with the distance D₂, the M1 tracks 1070 and 1071 are each shifted to the left from the gate structure 1016 with the distance D₂, and the M1 track 1072 is shifted to the left from the gate structure 1017 with the distance D₂.

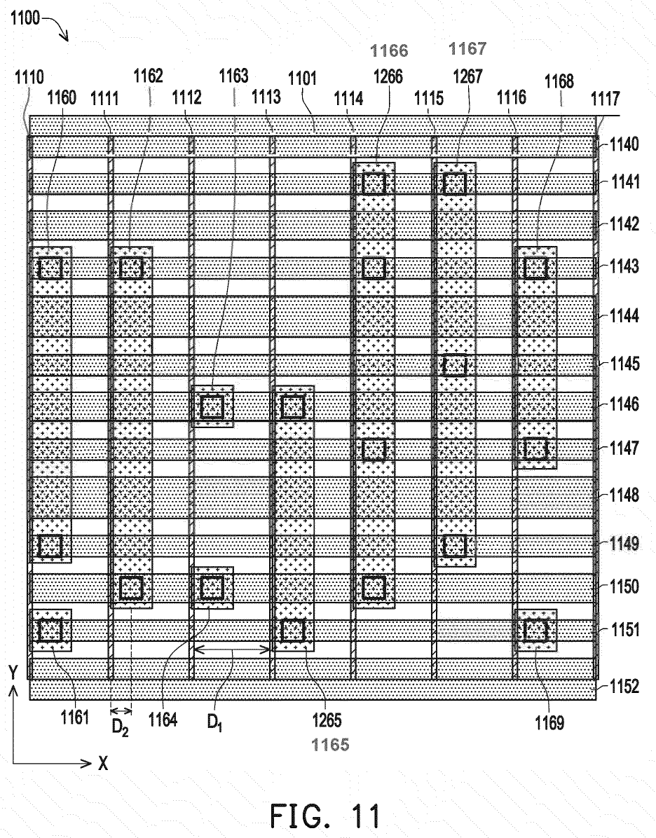

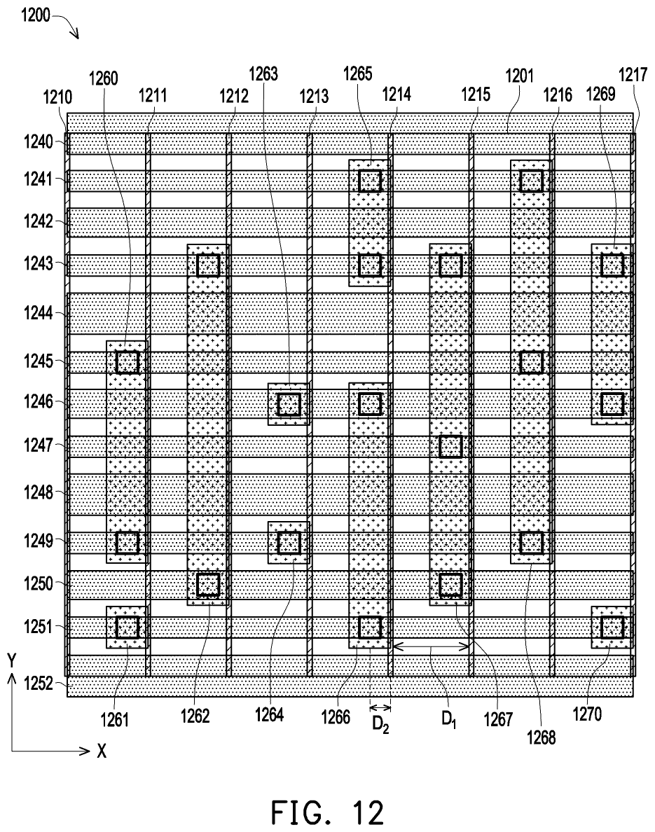

FIG. 11 and FIG. 12 illustrate layouts of example standard cells 1100 and 1200, respectively, in accordance with some embodiments. The standard cells 1100 and 1200 can operatively correspond to the same circuit component, e.g., a flip flop. It should be appreciated that the layouts of the standard cells 1100 and 1200 shown in FIGS. 11-12 have been simplified, and thus, each of the layouts can include any of various other components (e.g., patterns for forming respective active regions, MDs, VDs, VGs, etc.) while remaining within the scope of the present disclosure.

Referring first to FIG. 11, the standard cell 1100 includes a cell boundary 1101. Within the cell boundary 1101, the standard cell 1100 may include one or more active regions extending in the X-direction (not shown for clarity), gate structures 1110, 1111, 1112, 1113, 1114, 1115, 1116, and 1117 extending in the Y-direction, MDs extending in the Y-direction (not shown for clarity), M0 tracks 1140, 1141, 1142, 1143, 1144, 1145, 1146, 1147, 1148, 1149, 1150, 1151, and 1152 extending in the X-direction, and M1 tracks 1160, 1161, 1162, 1163, 1164, 1165, 1166, 1167, 1168, and 1169. As shown, the M1 tracks 1160 and 1161 are each shifted to the right from the gate structure 1110 with the distance D₂ which can be equal to or less than the gate pitch D₁, the M1 track 1162 is shifted to the right from the gate structure 1111 with the distance D₂, the M1 tracks 1163 and 1164 are each shifted to the right from the gate structure 1112 with the distance D₂, the M1 track 1165 is shifted to the right from the gate structure 1113 with the distance D₂, the M1 track 1166 is shifted to the right from the gate structure 1114 with the distance D₂, the M1 track 1167 is shifted to the right from the gate structure 1115 with the distance D₂, and the M1 tracks 1168 and 1169 are each shifted to the right from the gate structure 1116 with the distance D₂.

Referring next to FIG. 12, the standard cell 1200 includes a cell boundary 1201. Within the cell boundary 1201, the standard cell 1200 may include one or more active regions extending in the X-direction (not shown for clarity), gate structures 1210, 1211, 1212, 1213, 1214, 1215, 1216, and 1217 extending in the Y-direction, MDs extending in the Y-direction (not shown for clarity), M0 tracks 1240, 1241, 1242, 1243, 1244, 1245, 1246, 1247, 1248, 1249, 1250, 1251, and 1252 extending in the X-direction, and M1 tracks 1260, 1261, 1262, 1263, 1264, 1265, 1266, 1267, 1268, 1269, and 1270. As shown, the M1 tracks 1260 and 1261 are each shifted to the left from the gate structure 1211 with the distance D₂ which can be equal to or less than the gate pitch D₁, the M1 track 1262 is shifted to the left from the gate structure 1212 with the distance D₂, the M1 tracks 1263 and 1264 are each shifted to the left from the gate structure 1213 with the distance D₂, the M1 tracks 1265 and 1266 are each shifted to the left from the gate structure 1214 with the distance D₂, the M1 track 1267 is shifted to the left from the gate structure 1215 with the distance D₂, the M1 track 1268 is shifted to the left from the gate structure 1216 with the distance D₂, and the M1 tracks 1269 and 1270 are each shifted to the left from the gate structure 1217 with the distance D₂.

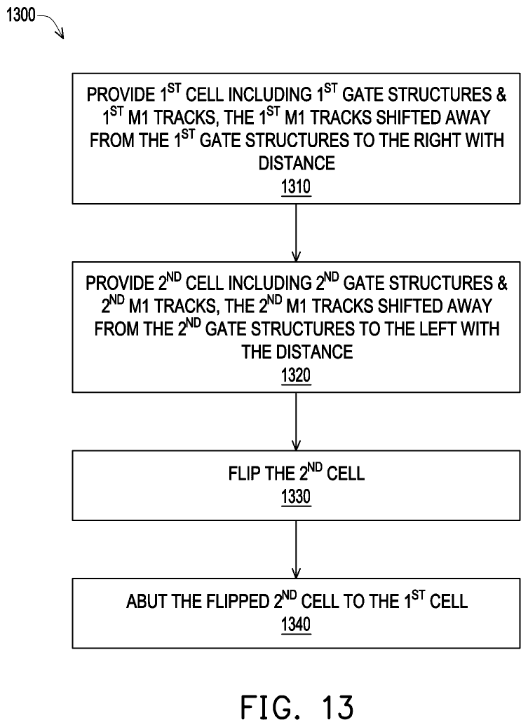

FIG. 13 illustrates a flow chart of a method 1300 for optimizing standard cell layout designs in integrated circuits, in accordance with some embodiments. The method 1300 can be a part of a method for fabricating an integrated circuit. For example, operation of the method 1300 can be configured for fabricating an integrated circuit based on the layouts (or standard cells) shown in FIGS. 1-12. Accordingly, the following discussion of the method 1300 may sometimes refer to the above figures. It should be noted that the method 1300 as shown in FIG. 13 is merely an example, and is not intended to limit the present disclosure. Thus, it is understood that the order of the operations of the method 1300 of FIG. 13 can be changed, for example, additional operations may be provided before, during, and after the method 1300, and that some operations may only be described briefly herein.

The method 1300 can start with operation 1310 of providing a first standard cell including a number of first gate structures and a number of first M1 tracks, in which the first M1 tracks are shifted away from the first gate structures to the left with a distance. In some embodiments, the first gate structures and the first M1 tracks can extend along the same lateral direction. Using the layout of the standard cell 100 shown in FIG. 1 as an example, the first standard cell 100 includes the first gate structures 110 to 120 and the first M1 tracks 166 to 174, extending in the Y-direction. In addition, the first standard cell 100 can include the active regions 102-104 extending in the X-direction, the M0 tracks 140 to 154 extending in the X-direction, and a plural number of via structures (e.g., VDs 122-130, VGs 132-138, V0s 156-164). In some embodiments, each of the first M1 tracks 166 to 174 is shifted to the left from a corresponding (e.g., nearest) one of the first gate structures 110 to 120 with the distance D₂. The distance D₂ can be equal to or less than the gate pitch D₁.

The method 1300 can proceed to operation 1320 of providing a second standard cell including a number of second gate structures and a number of second M1 tracks, in which the second M1 tracks are shifted away from the second gate structures to the right with the distance. In some embodiments, the second gate structures and the second M1 tracks can extend along the same lateral direction. Using the layout of the standard cell 200 shown in FIG. 2 as an example, the first standard cell 200 includes the second gate structures 210 to 220 and the second M1 tracks 266 to 274, extending in the Y-direction. In addition, the second standard cell 200 can include the active regions 202-204 extending in the X-direction, the M0 tracks 240 to 254 extending in the X-direction, and a plural number of via structures (e.g., VDs 222-230, VGs 232-238, V0s 256-264). In some embodiments, each of the second M1 tracks 266 to 274 is shifted to the right from a corresponding (e.g., nearest) one of the second gate structures 210 to 220 with the distance D₂. The distance D₂ can be equal to or less than the gate pitch D₁.

The method 1300 can proceed to operation 1330 of flipping the second standard cell. As shown in FIG. 3, the standard cell 200 can be flipped with respect to the Y-direction. After being flipped, the standard cell 200 can have its second M1 tracks 266 to 274 shifted to the left. That is, each of the second M1 tracks 266 to 274 is shifted to the left from the corresponding (e.g., nearest) one of the second gate structures 210 to 220 with the distance D₂.

The method 1300 can proceed to operation 1340 of abutting the flipped second standard cell to one or more of the first standard cells. Continuing with the same example of FIG. 3, the flipped second standard cell 200 can be placed to abut at least one of the first standard cells 100. As shown, the flipped second standard cell 200 is interposed between a pair of the first standard cells 100 along the X-direction. Over a given area for fabricating the integrated circuit, a plural number of layout rows can be formed or placed. In some embodiments, each of these layout rows can include or house one or more such flipped second standard cells, and each of the flipped second standard cells can be interposed between a corresponding pair of the first standard cells. As such, the flipped second standard cells can be each abutted to one or more first standard cells along the X-direction or the Y-direction.

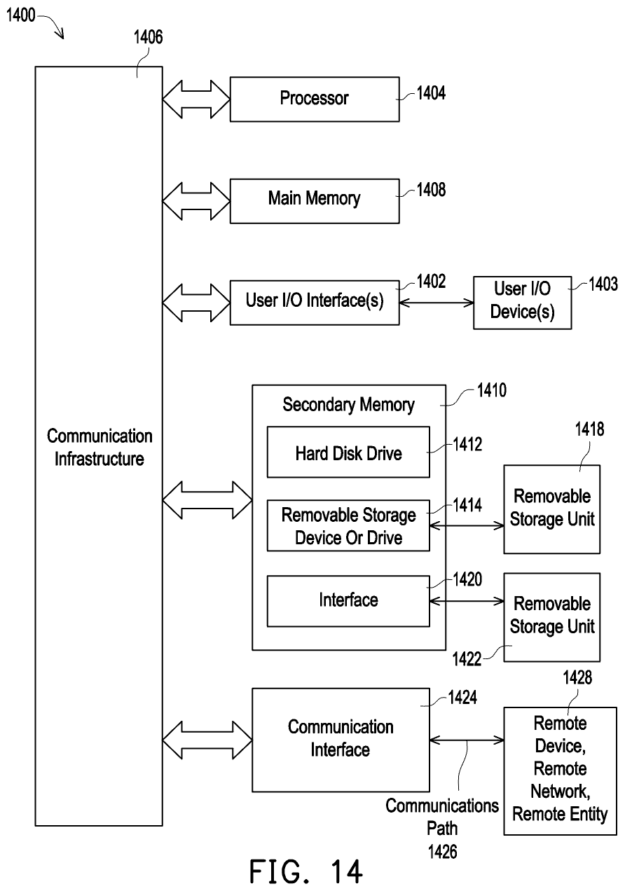

FIG. 14 illustrates an example computer system 1400, in accordance with some embodiments. The computer system 1400 can be any well-known computer capable of performing the functions and operations described herein. For example, and without limitation, the computer system 1400 can be capable of selecting standard cells to be optimized, for example, an EDA tool. The computer system 1400 can be used, for example, to execute one or more operations in the method 1300 of FIG. 13.

The computer system 1400 includes one or more processors (also called central processing units, or CPUs), such as a processor 1404. The processor 1404 is connected to a communication infrastructure or a bus 1406. The computer system 1400 also includes input/output device(s) 1403, such as monitors, keyboards, pointing devices, etc., that communicate with communication infrastructure or the bus 1406 through input/output interface(s) 1402. An EDA tool can receive instructions to implement functions and operations described herein e.g., the method 1300 of FIG. 13—via the input/output device(s) 1403. The computer system 1400 also includes a main or primary memory 1408, such as random access memory (RAM), main memory 1408 can include one or more levels of cache. The main memory 1408 has stored therein control logic (e.g., computer software) and/or data. In some embodiments, the control logic (e.g., computer software) and/or data can include one or more of the operations described above with respect to method 1300 of FIG. 13.

The computer system 1400 can also include one or more secondary storage devices or memory 1410. The secondary memory 1410 can include, for example, a hard disk drive 1412 and/or a removable storage device or drive 1414. The removable storage drive 1414 can be a floppy disk drive, a magnetic tape drive, a compact disk drive, an optical storage device, tape backup device, and/or any other storage device/drive. The removable storage drive 1414 can interact with a removable storage unit 1418. The removable storage unit 1418 includes a computer usable or readable storage device having stored thereon computer software (control logic) and/or data. The removable storage unit 1418 can be a floppy disk, magnetic tape, compact disk, DVD, optical storage disk, and/any other computer data storage device. The removable storage drive 1414 reads from and/or writes to removable storage unit 1418.

The secondary memory 1410 can include other means, instrumentalities or other approaches for allowing computer programs and/or other instructions and/or data to be accessed by the computer system 1400. Such means, instrumentalities or other approaches can include, for example, a removable storage unit 1422 and an interface 1420. Examples of the removable storage unit 1422 and the interface 1420 can include a program cartridge and cartridge interface (such as that found in video game devices), a removable memory chip (such as an EPROM or PROM) and associated socket, a memory stick and USB port, a memory card and associated memory card slot, and/or any other removable storage unit and associated interface. In some embodiments, the secondary memory 1410, removable storage unit 1418, and/or removable storage unit 1422 can include one or more of the operations described above with respect to the method 1300 of FIG. 13.

The computer system 1400 can further include a communication or network interface 1424. The communication interface 1424 enables the computer system 1400 to communicate and interact with any combination of remote devices, remote networks, remote entities, etc. (individually and collectively referenced by reference number 1428). For example, the communication interface 1424 can allow the computer system 1400 to communicate with remote devices 1428 over communications path 1426, which can be wired and/or wireless, and which can include any combination of LANs, WANs, the Internet, etc. Control logic and/or data can be transmitted to and from the computer system 1400 via the communication path 1426.

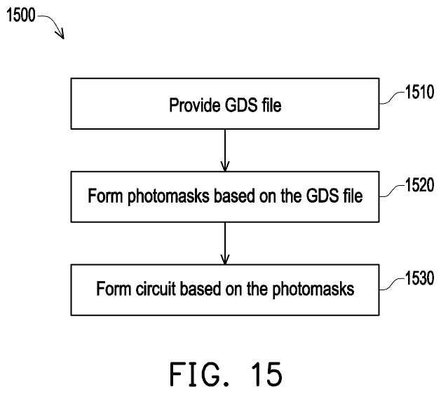

The operations in the preceding embodiments can be implemented in a wide variety of configurations and architectures. Therefore, some or all of the operations in the preceding embodiments, e.g., the method 1300 of FIG. 13 and method 1500 of FIG. 15 (described below) can be performed in hardware, in software or both. In some embodiments, a tangible apparatus or article of manufacture comprising a tangible computer useable or readable medium having control logic (software) stored thereon is also referred to herein as a computer program product or program storage device. This includes, but is not limited to, computer system 1400, main memory 1408, secondary memory 1410 and removable storage units 1418 and 1422, as well as tangible articles of manufacture embodying any combination of the foregoing. Such control logic, when executed by one or more data processing devices (such as the computer system 1400), causes such data processing devices to operate as described herein. In some embodiments, the computer system 1400 is installed with software to perform operations in the manufacturing of photomasks and circuits, as illustrated in method 1500 of FIG. 15 (described below). In some embodiments, the computer system 1400 includes hardware/equipment for the manufacturing of photomasks and circuit fabrication. For example, the hardware/equipment can be connected to or be part of element 1428 (remote device(s), network(s), entity(ies)) of the computer system 1400.

FIG. 15 illustrates an example method 1500 for circuit fabrication, according to some embodiments. Operations of the method 1500 can also be performed in a different order and/or vary. Variations of the method 1500 should also be within the scope of the present disclosure.

In operation 1510, a GDS file is provided. The GDS file can be generated by an EDA tool and contain the standard cell structures that have already been optimized using the disclosed method. The operation depicted in 1510 can be performed by, for example, an EDA tool that operates on a computer system, such as the computer system 1400 described above.

In operation 1520, photomasks are formed based on the GDS file. In some embodiments, the GDS file provided in operation 1510 is taken to a tape-out operation to generate photomasks for fabricating one or more integrated circuits. In some embodiments, a circuit layout included in the GDS file can be read and transferred onto a quartz or glass substrate to form opaque patterns that correspond to the circuit layout. The opaque patterns can be made of, for example, chromium or other suitable metals. Operation 1520 can be performed by a photomask manufacturer, where the circuit layout is read using a suitable software (e.g., EDA tool) and the circuit layout is transferred onto a substrate using a suitable printing/deposition tool. The photomasks reflect the circuit layout/features included in the GDS file.

In operation 1530, one or more circuits are formed based on the photomasks generated in operation 1520. In some embodiments, the photomasks are used to form patterns/structures of the circuit contained in the GDS file. In some embodiments, various fabrication tools (e.g., photolithography equipment, deposition equipment, and etching equipment) are used to form features of the one or more circuits.

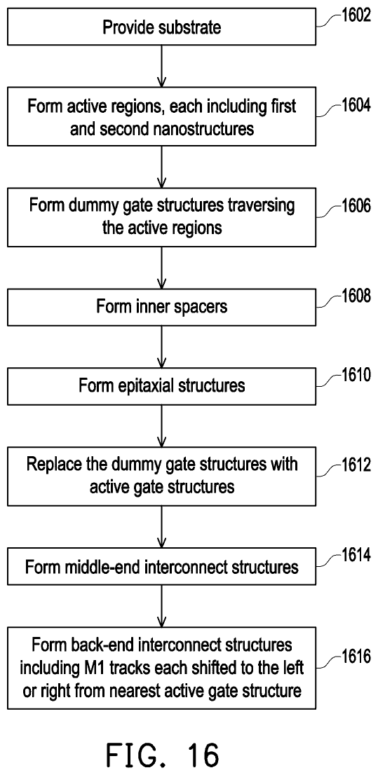

FIG. 16 illustrates a flowchart of a method 1600 to form a portion of an integrated circuit based on at least one of the layout 100 of FIG. 1 or 200 of FIG. 2, according to some embodiments of the present disclosure. It is noted that the method 1600 is merely an example and is not intended to limit the present disclosure. Accordingly, it is understood that additional operations may be provided before, during, and after the method 1600 of FIG. 16, and that some other operations may only be briefly described herein.

For example, the method 1600 starts with operation 1602 in which a substrate is provided. The method 1600 continues to operation 1604 in which a stack, including an alternating series of first nanostructures and second nanostructures stacked on top of one another, are formed. The stack may include a number of active regions (e.g., 102 and 104 of FIGS. 1, 202 and 204 of FIG. 2) each extending along a first lateral direction (e.g., the X-direction of FIGS. 1-2). In some embodiments, the first nanostructures can include silicon germanium (SiGe) sacrificial nanostructures, and the second nanostructures can include silicon (Si) channel nanostructures. The method 1600 continues to operation 1606 in which a number of dummy gate structures are formed to traverse the active regions. The dummy gate structures (e.g., 110-120 of FIG. 1, 210-220 of FIG. 2) can extend along a second lateral direction (e.g., the Y-direction of FIGS. 1-2) perpendicular to the first lateral direction. The method 1600 proceeds to operation 1608 in which inner spacers are formed by replacing end portions of each of the first nanostructures with a dielectric material. The method 1600 proceeds to operation 1610 in which a number of epitaxial structures are formed. The method 1600 proceeds to operation 1612 in which the dummy gate structures and the remaining first nanostructures are replaced with respective active gate structures. The method 1600 proceeds to operation 1614 in which a number of middle-end interconnect structures are formed. Each of the middle-end interconnect structures or MDs (e.g., 121-1 to 121-5 of FIG. 1, 221-1 to 221-5 of FIG. 2) can extend along the second lateral direction and interposed between adjacent ones of the active gate structures in the first lateral direction. The method 1600 proceeds to operation 1616 in which a number of back-end interconnect structures are formed. These back-end interconnect structures can include a number of M0 tracks (e.g., 140 to 154 of FIG. 1, 240 to 254 of FIG. 2) extending along the first lateral direction, and a number of M1 tracks (e.g., 166 to 174 of FIG. 1, 266 to 274 of FIG. 2) extending along the second lateral direction.

In some embodiments, each of the M1 tracks can be laterally shifted to the left or to the right from a nearest one of the active gate structures. For example, in FIG. 1, the M1 track 166 is shifted to the left away from the gate structure 112; the M1 track 168 is shifted to the left away from the gate structure 114; the M1 track 170 is shifted to the left away from the gate structure 116; the M1 track 172 is shifted to the left away from the gate structure 118; and the M1 track 174 is shifted to the left away from the gate structures 120. For another example, in FIG. 2, the M1 track 268 is shifted to the right away from the gate structure 212; the M1 track 270 is shifted to the right away from the gate structure 214; the M1 track 272 is shifted to the right away from the gate structure 216; and the M1 track 274 is shifted to the right away from the gate structure 218.

In one aspect of the present disclosure, an integrated circuit is disclosed. The integrated circuit includes a plurality of cells abutted to one another, each of the plurality of cells corresponding to a respective circuit component. Each of the plurality of cells includes: a plurality of active regions extending along a first lateral direction; a plurality of gate structures extending along a second lateral direction perpendicular to the first lateral direction and traversing one or more of the plurality of active regions; a plurality of first interconnect structures extending along the first lateral direction and vertically disposed above the plurality of gate structure; and a plurality of second interconnect structures extending along the second lateral direction and vertically disposed above the plurality of first interconnect structures. Each of the plurality of second interconnect structures is shifted from a corresponding one of the plurality of gate structures with a distance along the first lateral direction.

In another aspect of the present disclosure, a layout for forming an integrated circuit is disclosed. The layout includes a first cell having a first boundary and operatively corresponding to a circuit component, wherein the first cell comprising a plurality of first patterns for forming a first gate structure, a first interconnect structure vertically above the first gate structure, and a second interconnect structure vertically above the first interconnect structure, respectively, and wherein the first gate structure extends along a first lateral direction, the first interconnect structure extends along a second lateral direction perpendicular to the first lateral direction, and the second interconnect structure extends along the first lateral direction. The layout includes a second cell disposed with respect to the first cell along the second lateral direction or the first lateral direction, having a second boundary, and operatively corresponding to the circuit component, wherein the second cell comprising a plurality of second patterns for forming a second gate structure, a third interconnect structure vertically above the second gate structure, and a fourth interconnect structure vertically above the third interconnect structure, respectively, and wherein the second gate structure extends along the first lateral direction, the third interconnect structure extends along the second lateral direction, and the fourth interconnect structure extends along the first lateral direction. The second interconnect structure is shifted from the first gate structure along the second lateral direction with a distance, and the fourth interconnect structure is shifted from the second gate structure along the second lateral direction with the distance.

In yet another aspect of the present disclosure, a method is disclosed. The method includes forming an active region extending along a first lateral direction. The method includes forming a plurality of gate structures extending along a second lateral direction to traverse the active region. The method includes forming a number of first interconnect structures in a first metallization layer over the plurality of gate structures. The method includes forming a number of second interconnect structures in a second metallization layer over the first metallization layer. When viewed from the top, each of the second interconnect structure is shifted to the right or left from a nearest one of the gate structures along the first lateral direction with a distance.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit, comprising:
a plurality of cells abutted to one another, each of the plurality of cells corresponding to a respective circuit component;
wherein each of the plurality of cells comprises:
a plurality of active regions extending along a first lateral direction;
a plurality of gate structures extending along a second lateral direction perpendicular to the first lateral direction and traversing one or more of the plurality of active regions;
a plurality of first interconnect structures extending along the first lateral direction and vertically disposed above the plurality of gate structure; and
a plurality of second interconnect structures extending along the second lateral direction and vertically disposed above the plurality of first interconnect structures;
wherein each of the plurality of second interconnect structures is shifted from a corresponding one of the plurality of gate structures with a distance along the first lateral direction.

2. The integrated circuit of claim 1, wherein all the plurality of second interconnect structures are shifted to the left or to the right from the plurality of gate structures.

3. The integrated circuit of claim 1, wherein the distance is equal to or less than one half of a separation distance between adjacent ones of the gate structures along the first lateral direction.

4. The integrated circuit of claim 1, wherein at least a first one of the plurality of cells, a second one of the plurality of cells, and a third one of the plurality of cells correspond to a same circuit component.

5. The integrated circuit of claim 4, wherein the first to third cells are abutted to one another along the first lateral direction, with the second cell interposed between the first and third cells.

6. The integrated circuit of claim 5, wherein the first cell comprises at least one of its first interconnect structures reaching a first edge of a boundary of the first cell, the second cell comprises at least one of its first interconnect structures reaching a first edge of a boundary of the second cell, and the third cell comprises at least one of its first interconnect structures reaching a first edge of a boundary of the third cell.

7. The integrated circuit of claim 6, wherein the boundary of the second cell comprises a second edge reaching the first edge of the boundary of the first cell, and the boundary of the third cell comprises a second edge reaching the first edge of the boundary of the second cell.

8. The integrated circuit of claim 6, wherein the at least one first interconnect structure of the first cell does not exceed the first edge of the boundary of the first cell, the at least one first interconnect structure of the second cell does not exceed the first edge of the boundary of the second cell, and the at least one first interconnect structure of the third cell does not exceed the first edge of the boundary of the third cell.

9. The integrated circuit of claim 1, wherein at least one of the first interconnect structures is coupled to different ones of the shifted second interconnect structures through via structures, respectively.

10. The integrated circuit of claim 9, wherein the via structures are vertically disposed between the first interconnect structures and the second interconnect structures.

11. The integrated circuit of claim 1, wherein the circuit component comprises one of: an inverter, an AND-OR-Inverter, an AND gate, or a flip flop.

12. A layout for forming an integrated circuit, comprising:
a first cell having a first boundary and operatively corresponding to a circuit component, wherein the first cell comprising a plurality of first patterns for forming a first gate structure, a first interconnect structure vertically above the first gate structure, and a second interconnect structure vertically above the first interconnect structure, respectively, and wherein the first gate structure extends along a first lateral direction, the first interconnect structure extends along a second lateral direction perpendicular to the first lateral direction, and the second interconnect structure extends along the first lateral direction; and
a second cell disposed with respect to the first cell along the second lateral direction or the first lateral direction, having a second boundary, and operatively corresponding to the circuit component, wherein the second cell comprising a plurality of second patterns for forming a second gate structure, a third interconnect structure vertically above the second gate structure, and a fourth interconnect structure vertically above the third interconnect structure, respectively, and wherein the second gate structure extends along the first lateral direction, the third interconnect structure extends along the second lateral direction, and the fourth interconnect structure extends along the first lateral direction;
wherein the second interconnect structure is shifted from the first gate structure along the second lateral direction with a distance, and the fourth interconnect structure is shifted from the second gate structure along the second lateral direction with the distance.

13. The layout of claim 12, wherein the distance is equal to or less than one half of a separation distance between the first gate structure and second gate structure along the second lateral direction.

14. The layout of claim 12, wherein the first interconnect structure extends toward an edge of the first boundary, with the third interconnect structure spaced away from an edge of the second boundary.

15. The layout of claim 14, wherein the edge of the first boundary and the edge of the second boundary, each extending along the first lateral direction, are abutted to each other.

16. The layout of claim 14, wherein the first interconnect structure does not extend beyond the edge of the first boundary.

17. The layout of claim 14, wherein the second interconnect structure and the fourth interconnect structure, respectively coupled to the first interconnect structure and the third structure, are operatively configured as a same input/output terminal of the circuit component.

18. A method, comprising:
forming an active region extending along a first lateral direction;
forming a plurality of gate structures extending along a second lateral direction to traverse the active region;
forming a number of first interconnect structures in a first metallization layer over the plurality of gate structures; and
forming a number of second interconnect structures in a second metallization layer over the first metallization layer, wherein, when viewed from the top, each of the second interconnect structure is shifted to the right or left from a nearest one of the gate structures along the first lateral direction with a distance.

19. The method of claim 18, wherein the distance is equal to or less than one half of a separation distance between adjacent ones of the plurality of gate structures along the first lateral direction.

20. The method of claim 18, further comprising:
forming a number of third interconnect structures extending along the second lateral direction;
wherein the third interconnect structures are vertically interposed between the gate structures and the first metallization layer, and wherein, when viewed from the top, each of the second interconnect structure is shifted to the right or left from a nearest one of the third interconnect structures along the first lateral direction with the distance.
